(19) United States
(12) Patent Application Publication
(10) Pub. No.: US 2024/0395873 A1
(43) Pub. Date: Nov. 28, 2024

(54) III-N SILICON SEMICONDUCTOR WAFER

(71) Applicant: AZUR SPACE Solar Power GmbH, Heilbronn (DE)

(72) Inventors: Atsushi NISHIKAWA, Dresden (DE); Alexander LOESING, Lippstadt (DE)

(73) Assignee: AZUR SPACE Solar Power GmbH, Heilbronn (DE)

(21) Appl. No.: 18/794,638

(22) Filed: Aug. 5, 2024

Related U.S. Application Data
(63) Continuation of application No. PCT/EP2022/000113, filed on Dec. 19, 2022.

(30) Foreign Application Priority Data
Feb. 3, 2022 (DE) 10 2022 000 425.9

(51) Int. Cl. H01L 29/20; H01L 21/02; H01L 21/18

(52) U.S. Cl. CPC H01L 29/2003; H01L 21/02164; H01L 21/187

(57) ABSTRACT

A III-N silicon semiconductor wafer having an upper layer region and a lower layer region, wherein the upper layer region has a nitride layer with a formed III-N layer, and the lower layer region includes a silicon layer. The semiconductor wafer has a total thickness of at least 1.2 mm and is disk-shaped, and the semiconductor wafer is divided along a total thickness into the upper layer region and the lower layer region. The upper layer region has a circumferential edge region, and the upper layer region has a first maximum diameter of at least 145 mm, and the upper layer region has a thickness greater than 30 μm and less than 950 μm. The lower layer region has a second maximum diameter, and a connection region is formed between the upper layer region and the lower layer region, wherein the connection region has a third diameter.

This nonprovisional application is a continuation of International Application PCT/EP2022/000113, which was filed on Dec. 19, 2022, and which claims priority to German Patent Application No. 10 2022 000 425.9 which was filed in Germany on Feb. 3, 2022, and which are all herein incorporated by reference.

### BACKGROUND OF THE INVENTION

### Field of the Invention

The invention relates to a III-N silicon semiconductor wafer.

### Description of the Background Art

Silicon semiconductor wafers with a nitride layer resting thereon are known from DE 10 2006 030 305 and DE 102 569 11.

From U.S. Pat. No. 2,022,367 188 A1, a method is known for joining two silicon substrate wafers with different crystal orientation and a silicon dioxide intermediate layer, wherein the three layers each have the same diameter. Each upper Si wafer has an orientation of <100>, the lower Si wafer has an orientation of <111>. Each oxide layer has a thickness of more than 1 μm. The object of the method or of the arrangement is to suppress a warping during the production of a nitride layer on the upper Si wafer with a thickness of more than 1.0 μm.

From U.S. Pat. No. 2,007,069 335 A1, a method is known for producing an SOI wafer, wherein the upper silicon layer is designed as an active layer for producing components and has a thickness of less than 10 μm. The object of the method is to reduce the disadvantages caused as a result of the CMP process such as, e.g., the area of the edge region in which the active layer in the edge region has incomplete joining.

A method for rounding the edges of an individual semiconductor wafer is known from CN 1058 142 45 B.

### SUMMARY OF THE INVENTION

It is therefore an object of the invention to provide a device that advances the state of the art.

According to the subject matter of the invention, a III-N silicon semiconductor wafer is provided, having an upper layer region with a top surface and a lower layer region with a bottom surface.

The upper layer region has a nitride layer with a formed III-N layer. The lower layer region includes a silicon layer or consists of a silicon layer.

The semiconductor wafer has a total thickness of at least 1.2 mm and is disk-shaped in design. In addition, the semiconductor wafer is divided along the total thickness into the upper layer region and the lower layer region. The maximum thickness of the semiconductor wafer is 3 mm.

The upper layer region has a circumferential edge region and a first maximum diameter of at least 145 mm.

The upper layer region has a thickness greater than 30 μm and less than 950 μm. The lower layer region has a second maximum diameter, and a connection region is formed between the upper layer region and the lower layer region.

The connection region has a third diameter, wherein the third diameter is smaller than the first maximum diameter. The third diameter is made smaller than the second maximum diameter or as large as the second maximum diameter.

The first maximum diameter corresponds to the second maximum diameter, or the first maximum diameter is formed differently from the second maximum diameter.

It should be noted that the term “III-N” refers to the column of the Ill-valued elements of the periodic table, such as, in particular, boron, aluminum, gallium, and indium in combination with nitrogen. In other words, in addition to silicon, the semiconductor wafer has, in particular in the nitride layer, at least the element nitrogen in a compound with one of the elements from column III of the periodic table. In particular, the term “III-N” also includes layers such as AlGaN or GaN.

Preferably, a layer including or consisting of GaN is formed at the top surface of the nitride layer.

An advantage of the large thickness of the semiconductor wafer is that the semiconductor wafer formed predominantly of silicon is not or is only slightly deformed in tension or compression during a production of the nitride layer. In other words, the semiconductor wafer formed predominantly of silicon is only slightly or is not warped during production of the nitride layer at the top surface. In one improvement, the bending of the semiconductor wafer is less than 300 μm or less than 100 μm or less than 30 μm.

Another advantage is that, with the large thickness of at least 1.2 mm, preferably two silicon semiconductor wafers of thicknesses that are typically used can be joined in an economical manner in order to achieve the desired total thickness.

The thicknesses of semiconductor wafers that are typically used, also often referred to as SEMI standard thicknesses, are listed in Table 1 as a function of the diameter of the semiconductor wafer. In addition, the minimum thickness according to the invention as a function of the diameter, as well as the typical thicknesses according to the present invention, are listed for purposes of comparison.

| | | | | |
|---|---|---|---|---|
| Diameter | 150 mm | 200 mm | 300 mm | >300 mm |
| | | | | (e.g.: 450 mm) |
| SEMI standard | 625 μm to | 725 μm | 775 μm | ≥775 μm (e.g., for |
| thickness, i.e., typical | 675 μm | | | 450 mm diameter: |
| thickness in the | | | | 925 μm) |
| semiconductor | | | | |
| industry | | | | |
| Minimum thickness | 1.2 mm | 1.2 mm | 1.2 mm | 1.2 mm |
| according to the | | | | |
| invention | | | | |
| Typical minimum | 1.2 mm | 1.5 mm | >1.5 mm | 1.5 mm-3 mm |
| thickness for forming | | | | |
| a nitride layer | | | | |

It is a matter of course that the diameters listed in Table 1 can have a tolerance, generally of up to +/−200 μm. In addition, it should be noted that the respective tolerances for the diameters can also made larger or smaller. It should also be noted that, in another improvement, the semiconductor wafers also have different diameters, wherein the minimum thickness for all diameters is larger than 1.0 mm, however.

The upper layer region can include a silicon layer or consists of a silicon layer, wherein the nitride layer rests on the silicon layer and forms the top surface of the semiconductor wafer. The upper layer region can include a silicon semiconductor wafer in accordance with the SEMI standard thickness.

The thickness of the upper layer region can be between 100 μm and 900 μm or between 500 μm and 800 μm.

The silicon layer of the upper layer region can have a thickness between 30 μm and 950 μm or between 100 μm and 900 μm or between 500 μm and 800 μm.

The thickness D2 of the lower layer region USB can be greater than 10 μm and less than 950 μm.

The semiconductor wafer can be formed of more than 40% or more than 60% or more than 80% and at most 90% or at most 98% or at most 99% silicon.

The semiconductor wafer can be formed monolithically along the total thickness. In other words, the entire semiconductor wafer is made as a single piece.

The semiconductor wafer can have a bonding surface in the connection region, which is to say in the region between the upper layer region and the lower layer region. In other words, the semiconductor wafer has a two-piece construction. The semiconductor wafer is joined at the bonding surface. It is a matter of course that, in some examples, aids such as adhesive or metal layers or a combination of multiple materials are used in joining.

A semiconductor bond can be formed at the bonding surface. It should be noted that the term semiconductor bond is used synonymously with the term wafer bond. The upper region can be integrally joined directly to the lower region, preferably without the formation of intermediate layers. Intermediate layers are understood in this context as layers that have a different chemical composition from the chemical composition of the two semiconductor wafers that are joined.

The semiconductor bond can include a silicon dioxide layer, wherein the silicon dioxide layer has a thickness between a monolayer and a thickness less than 10 μm or less than 1 μm or less than 100 nm.

The first maximum diameter can differ by at most 10 mm or by at most 2 mm from the second maximum diameter. In an example, the second maximum diameter is at most 5 mm smaller than or at most 2 mm larger than the first maximum diameter.

The first maximum diameter can be the same size as the second maximum diameter or the first maximum diameter corresponds to the second maximum diameter.

The circumferential edge region of the upper layer region may be angular or not angular in design. The circumferential edge region of the upper layer region iscan be rounded or the circumferential edge region of the upper layer region is designed according to the JEITA standard or the SEMI standard.

The lower layer region can have a circumferential, rounded edge region. The lower layer region can have an increasing diameter and/or a decreasing diameter along the thickness D2 of the semiconductor wafer.

The nitride layer can include one layer or multiple III-N and/or metal nitride layers. In particular, single or multiple layers including or consisting of AlGaN, GaN, AlN, InN, and TiN are formed in the nitride layer.

In an example, multiple nitride layers are formed.

The nitride layer can have a thickness of at least 1 μm or of at least 4 μm and at most a thickness of 30 μm. The GaN layer at the top surface of the upper layer region can have a thickness between 0.5 μm and 10 μm or between 1.0 μm and 5 μm.

The upper circumferential edge region may not include a right-angled edge. The upper circumferential edge region and the lower circumferential edge region can each be edge-rounded.

It should be noted that the total thickness GD is formed as a sum of the thickness D1 of the upper layer region and the thickness D2 of the lower layer region and the thickness D3 of the nitride layer.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a view of an example of a III-N silicon semiconductor wafer,

FIG. 2 shows a view of an example of a III-N silicon semiconductor wafer,

FIG. 3 shows a view of an example of a III-N silicon semiconductor wafer,

FIG. 4 shows a view of an example of a III-N silicon semiconductor wafer.

### DETAILED DESCRIPTION

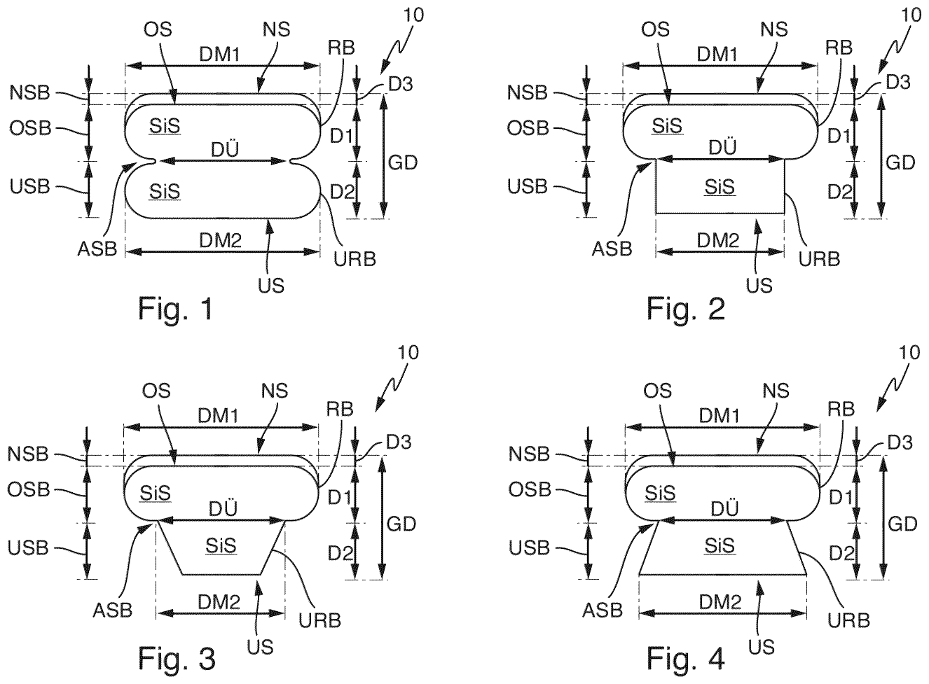

The illustration in FIG. 1 shows a first example having a III-N silicon semiconductor wafer 10 with an upper layer region OSB with a top surface OS and a thickness D1 and a lower layer region USB with a thickness D2 with a bottom surface US, wherein a nitride layer NSB with a thickness D3 is formed on the top surface OS of the upper layer region OSB.

The upper layer region OSB has a silicon layer SIS, wherein the nitride layer NSB rests on the silicon layer SIS and forms the top surface NS. The silicon layer SIS of the upper layer region OSB is between 100 μm and 950 μm.

The nitride layer NSB includes at least one III-N and/or one metal nitride layer.

In the depicted example, a thin III-N layer is formed on the surface NS of the nitride layer NSB. Preferably, the III-N layer includes or consists of GaN.

It is a matter of course that the III-N layer is additionally or alternatively formed at a different location on the nitride layer NSB in an example that is not shown.

The nitride layer NSB has a thickness of at least 1 μm or of at least 4 μm and at most a thickness of 30 μm.

The thickness D1 of the upper layer region OSB is less than 950 μm. The thickness D2 of the lower layer region USB is greater than 10 μm and less than 950 μm.

The lower layer region USB includes or consists of a silicon layer SIS.

The semiconductor wafer 10 has a total thickness GD of at least 1.2 mm and is disk-shaped in design. The maximum thickness of the semiconductor wafer 10 is 3 mm.

As explained above, the semiconductor wafer 10 is divided along the total thickness GD into the upper layer region OSB and the lower layer region USB. The upper layer region OSB has a circumferential edge region RB, wherein the upper edge region RB does not have a right-angled edge, but instead has a rounded edge. In addition, the upper layer region OSB has a first maximum diameter DM1 of at least 145 mm.

The lower layer region USB has a second maximum diameter DM2, wherein the lower edge region URB does not have a right-angled edge, but instead has a rounded edge. Formed between the upper layer region OSB and the lower layer region USB is a connection region ASB, wherein the connection region ASB has a third diameter DU. In this case, the first maximum diameter DM1 corresponds to the second maximum diameter DM2.

The third diameter DÜ is made smaller than the first maximum diameter DM1 and smaller than the second maximum diameter DM2.

Between the upper layer region OSB and the lower layer region USB, a semiconductor bond is formed at the connection region ASB.

The first maximum diameter DM1 differs by at most 2 mm from the second maximum diameter DM2. The circumferential edge region RB of the upper layer region OSB preferably is rounded in design or formed in a shape according to the JEITA standard or the SEMI standard.

The lower layer region USB has a circumferential, rounded edge region URB. The lower layer region USB includes silicon, wherein an oxide layer is formed at the bottom surface US in an example.

Shown in the illustration in FIG. 2 is a second example of a semiconductor wafer. Only the differences from the illustration in FIG. 1 are explained below.

The lower layer region USB has a constant diameter DM2 along the thickness D2 starting from the connection region ASB toward the bottom surface US.

Shown in the illustration in FIG. 3 is a third example of a semiconductor wafer. Only the differences from the illustration in FIG. 1 are explained below.

The lower layer region USB has a decreasing diameter DM2 along the thickness D2 starting from the connection region ASB toward the bottom surface US.

Shown in the illustration in FIG. 4 is a fourth example of a semiconductor wafer. Only the differences from the illustration in FIG. 1 are explained below.

The lower layer region USB has an increasing diameter DM2 along the thickness D2 starting from the connection region ASB toward the bottom surface US.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A III-N silicon semiconductor wafer comprising:
an upper layer region with a top surface;
a lower layer region with a bottom surface; and
a connection region formed between the upper layer region and the lower layer region,
wherein the upper layer region includes a nitride layer with a formed III-N layer,
wherein the lower layer region includes a silicon layer or consists of a silicon layer,
wherein the semiconductor wafer has a total thickness of at least 1.2 mm and is disk-shaped in design,
wherein the semiconductor wafer is divided along the total thickness into the upper layer region and the lower layer region,
wherein the upper layer region has a circumferential edge region,
wherein the upper layer region has a first maximum diameter of at least 145 mm, and the upper layer region has a thickness greater than 30 μm and less than 950 μm,
wherein the lower layer region has a second maximum diameter,
wherein the connection region has a transition region with a bonding surface,
wherein the first maximum diameter corresponds to the second maximum diameter or the first maximum diameter is formed differently from the second maximum diameter,
wherein the connection region has a third diameter that is made smaller than the first maximum diameter,
wherein the third diameter is made smaller than the second maximum diameter or as large as the second maximum diameter,
wherein the semiconductor wafer is formed monolithically along the total thickness or the semiconductor wafer has a semiconductor bond at the bonding surface, and
wherein the semiconductor bond is formed without the formation of intermediate layers or includes a silicon dioxide layer.

2. The III-N silicon semiconductor wafer according to claim 1, wherein the silicon dioxide layer has a thickness between a monolayer and a thickness less than 10 μm or less than 1 μm or less than 100 nm.

3. The III-N silicon semiconductor wafer according to claim 1, wherein the semiconductor wafer if formed of more than 40% or more than 60% or more than 80% but a maximum of 99% silicon.

4. The III-N silicon semiconductor wafer according to claim 1, wherein the first maximum diameter differs by at most 10 mm from the second maximum diameter, or the first maximum diameter corresponds to the second maximum diameter, or the first and second diameters are the same size.

5. The III-N silicon semiconductor wafer according to claim 1, wherein the second maximum diameter is at most 5 mm smaller than or at most 2 mm larger than the first maximum diameter.

6. The III-N silicon semiconductor wafer according to claim 1, wherein the circumferential edge region of the upper layer region is angular or not angular in design, or the circumferential edge region of the upper layer region is rounded in design, or the circumferential edge region of the upper layer region is designed according to the JEITA standard or the SEMI standard.

7. The III-N silicon semiconductor wafer according to claim 1, wherein the lower layer region has a circumferential, rounded edge region.

8. The III-N silicon semiconductor wafer according to claim 1, wherein the lower layer region has an increasing diameter and/or a decreasing diameter along a thickness.

9. The III-N silicon semiconductor wafer according to claim 1, wherein the nitride layer includes one or multiple III-N and/or metal nitride layers.

10. The III-N silicon semiconductor wafer according to claim 1, wherein the nitride layer has a thickness of at least 1 μm or of at least 4 μm and at most a thickness of 30 μm.

11. The III-N silicon semiconductor wafer according to claim 1, wherein the upper circumferential edge region does not include a right-angled edge.

12. The III-N silicon semiconductor wafer according to claim 1, wherein the upper layer region includes a silicon layer or consists of a silicon layer.

13. The III-N silicon semiconductor wafer according to claim 12, wherein the thickness of the silicon layer of the upper layer region is between 100 μm and 900 μm or between 500 μm and 800 μm.

14. The III-N silicon semiconductor wafer according to claim 1, wherein the nitride layer has a layer including or consisting of GaN at the top surface (NS).
